(19) United States
(12) Patent Application Publication
(10) Pub. No.: US 2025/0366230 A1
(43) Pub. Date: Nov. 27, 2025

(54) PHOTODETECTOR DEVICE HAVING LIGHTLY DOPED LAYER

(71) Applicant: TAIWAN SEMICONDUCTOR MANUFACTURING COMPANY LTD., HSINCHU (TW)

(72) Inventors: SHIH-MIN HUANG, HSINCHU COUNTY (TW); TZU-JUI WANG, KAOHSIUNG CITY (TW); CHI-HSIEN CHUNG, NEW TAIPEI CITY (TW); CHIA-CHI HSIAO, CHANGHUA COUNTY (TW); KUO-CHIN HUANG, YILAN COUNTY (TW); CHEN-JONG WANG, HSINCHU COUNTY (TW)

(21) Appl. No.: 18/672,044

(22) Filed: May 23, 2024

(51) Int. Cl. H01L 27/146

(52) U.S. Cl. CPC H10F 39/8033

(57) ABSTRACT

A photodetector device is provided. The photodetector device includes a substrate; an absorption region disposed within the substrate and in proximity to a surface of the substrate; a multiplication region disposed within the substrate and separated from the absorption region; and a channel region disposed between the multiplication region and the absorption region. The channel region and the multiplication region meet at a p-n junction. The absorption region includes a bulk region having a first p-type doping concentration; and a lightly doped layer under the bulk region and in proximity to a bottom side of the absorption region. The lightly doped layer has a second p-type doping concentration less than the first p-type doping concentration.

### BACKGROUND

Image sensors are solid-state devices that are configured to convert incoming light (e.g., photons) into an electrical signal. The electrical signal is then provided to a processor that can convert the electrical signal to data that can be stored and/or viewed by a user. Integrated chips (ICs) with image sensors are used in a wide range of modern day electronic devices, such as cell phones, security cameras, medical devices, etc.

### BRIEF DESCRIPTION OF THE DRAWINGS

Aspects of the present disclosure are best understood from the following detailed description when read with the accompanying figures. It is noted that, in accordance with the standard practice in the industry, various structures are not drawn to scale. In fact, the dimensions of the various structures may be arbitrarily increased or reduced for clarity of discussion.

FIG. 1 illustrates a cross-sectional view of a photodetector with a heterojunction between semiconductor materials according to some embodiment of the present disclosure.

FIG. 2 illustrates a cross-sectional view of a photodetector device according to some embodiment of the present disclosure.

FIG. 3 illustrates a top view corresponding to the photodetector device of FIG. 2 at a line A-A′.

FIG. 4 illustrates a cross-sectional view of a photodetector device according to some embodiment of the present disclosure.

FIG. 5A illustrates a cross-sectional view of a photodetector device according to some embodiment of the present disclosure.

FIG. 5B illustrates a cross-sectional view of a photodetector device according to some embodiment of the present disclosure.

FIG. 6 illustrates a cross-sectional view of a photodetector device according to some embodiment of the present disclosure, wherein the photodetector device has a base portion of a surface region that is counter doped and adjacent to a channel region.

FIG. 7 illustrates a cross-sectional view of a first and a second photodetector devices arranged side-by-side and separated by an isolation structure according to some embodiment of the present disclosure.

FIGS. 8 and 9 illustrate a cross-sectional view and a top view of according to some embodiments of the present disclosure, wherein a photodetector has a channel region at a heterojunction interface.

FIGS. 10 and 11 illustrate a cross-sectional view and a top view of according to some embodiments of the present disclosure, wherein a photodetector has a channel region at a heterojunction interface.

FIG. 12 illustrates a cross-sectional view of some embodiments of the present disclosure, wherein a photodetector has a channel region at a heterojunction interface.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper”, “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first”, “second” and “third” describe various elements, components, regions, layers and/or sections, these elements, components, regions, layers and/or sections should not be limited by these terms. These terms may be only used to distinguish one element, component, region, layer, or section from another. The terms such as “first”, “second”, and “third” when used herein do not imply a sequence or order unless clearly indicated by the context.

Photodetectors are semiconductor devices designed to convert energy from a radiation source (e.g., light, infrared radiation, x-rays, etc.) into electrical current. Photons or energy from the radiation source incident on an absorption region of a photodetector are absorbed by a semiconductor material of the absorption region. The absorption generates electron-hole pairs separated by an electric field of the photodetector to generate a flow of current (e.g., photocurrent) across a p-n junction within the photodetector where the current is proportional to an intensity of the incident radiation source.

Some photodetectors, for example, avalanche photodiodes (APDs), single photon avalanche diodes (SPADs), PN, PIN photodetectors, or the like, utilize different semiconductor materials within the photodetector structure. For example, germanium (Ge) can be used in the absorption region, while silicon (Si) serves as a bandgap material and base substrate that facilitates electron channeling from the germanium absorption region to other circuit components through doping regions, electrical wires, and contacts. These devices are heterojunction devices as they have an interface between two different semiconductor types or materials with distinct energy band structures (e.g., Ge—Si interface). Additionally, heterojunction devices can include a p-n junction between the doped absorption region and a doped region of the base substrate separated by an intrinsic region. That is, an interface at the heterojunction can be between a doped region of an epitaxial material and an intrinsic region of a semiconductor material. While heterojunction devices offer advantages like enhanced carrier mobility, high speed-performance, and lower power consumption, they can also exhibit adverse characteristics like dark current leakage due to high defect densities at the heterojunction interface. The defect densities at the heterojunction interface (Ge—Si interface), can arise from a lattice mismatch, band offset, and interface states between different crystal structures of the materials with differing bandgaps. As a result, heterojunction devices can suffer from low electron transfer ratios since the defects at the heterojunction can hinder electron transfer.

The present disclosure, in some embodiments, relates to a heterojunction device having a photodetector with an absorption region of an epitaxial material (e.g., a Ge semiconductor material) surrounded by a semiconductor substrate (e.g., a Si semiconductor material) that facilitates electron channeling from the absorption region to other circuit components through doping regions, electrical wires, and contacts. The heterojunction device has an enhanced channel region (hereinafter referred to as “channel region”) at the heterojunction between the epitaxial material and a doped region of the base substrate. The channel region is doped with a first doping type that is opposite a second doping type of the absorption region, thus a p-n junction is formed at the heterojunction which increases the electron transfer rate through the heterojunction by “funneling” electrons through the heterojunction interface. As a result, the heterojunction interface is enhanced thereby increasing the electron transfer rate at the interface.

Furthermore, the absorption region of the epitaxial material surrounded by a semiconductor substrate may have an increased photo-electron collection efficiency compared with some comparative embodiments since the absorption region of the epitaxial material further include an additional doping layer.

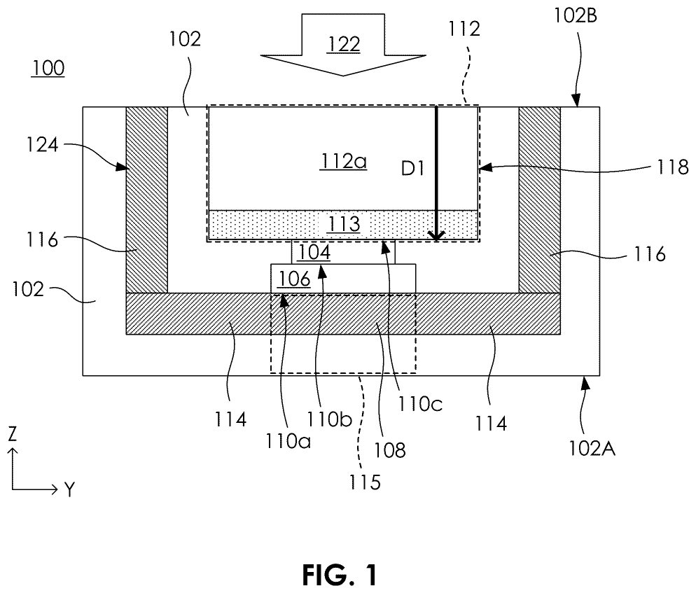

FIG. 1 illustrates a cross-sectional view of some embodiments of a photodetector device 100 with a channel region that is doped and meets an absorption region. In some embodiments, the photodetector device 100 is an avalanche photodetector or a single-photon avalanche diode.

Photodetector device 100 includes a semiconductor substrate 102 including a semiconductor material. The semiconductor substrate 102 has a first surface 102A and a second surface 102B opposite to the first surface 102A. An absorption region 112 is disposed within the semiconductor substrate 102 and in proximity to the first surface 102A of the semiconductor substrate 102. The absorption region 112 includes an epitaxial material different than the semiconductor material. In some embodiments, the absorption region 112 has a fill factor of 1% to 99% of the area laterally spanned by the photodetector device 100 with a height of 0.1 micrometers to 3 micrometers.

In some embodiments, the semiconductor material is silicon (Si) and the epitaxial material is germanium (Ge), but it is understood that the materials can be reversed. In some embodiments, the absorption region 112 is a germanium-based absorption region disposed within a silicon substrate. In some embodiments, for example, the absorption region 112 can include a p-type dopant. In some embodiments, a bulk region 112a of the absorption region 112 is Ge p-type doped to a doping concentration in a range from about from about 5e16 atoms/cm³ to about 5e17 atoms/cm³. In some embodiments, the bulk region 112a of the absorption region 112 is substantially a uniform boron doped bulk Ge. Furthermore, a heterojunction interface 118 can be located at a surface of the absorption region 112 that abuts a surface of the semiconductor substrate 102. In some embodiments, the heterojunction interface 118 is a Ge—Si interface.

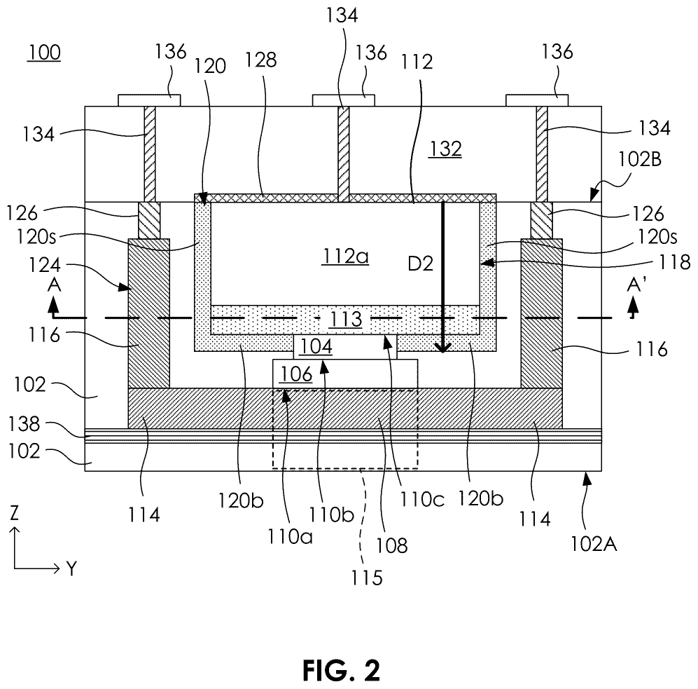

The heterojunction interface 118 is present where outer sidewalls and a lower surface of the absorption region 112 meet inner sidewalls and a recessed upper surface, respectively, of the semiconductor substrate 102. In some embodiments (e.g., in FIG. 2), the semiconductor substrate 102 is doped at the heterojunction interface 118. In some embodiments, the heterojunction interface 118 includes a Ge—Si alloy having a lattice constant ranging between approximately 56.6 nanometers (nm) and approximately 54.3 nm. In some cases, the heterojunction interface 118 can have a thickness ranging from 1 angstrom (Å) to 20 nm, from 10 Å to 10 nm, or other similar values. In some embodiments, the heterojunction interface can have a cross-section that is U-shaped.

A multiplication region 115 is disposed within the semiconductor substrate 102 and is separated from the absorption region 112. In such example of SAM (separated absorption and multiplication) structure, the absorption region 112 and the multiplication region 115 (e.g., an avalanche layer) are separated to suppress an increase of dark current induced by a narrow gap semiconductor. The multiplication region 115 includes a first doped region 106 arranged below the absorption region 112 (e.g., epitaxial material) and a second doped region 108 arranged below and abutting the first doped region 106 at a first p-n junction 110a. In some embodiments, the first doped region 106 and the second doped region 108 have different doping types. For example, the first doped region 106 can be p-type and the second doped region 108 can be n-type. Thus, in some embodiments, the multiplication region 115 includes an n-type region with an n-type dopant and a p-type region with a p-type dopant.

In some embodiments of the present disclosure, in order to increase the photo-electron collection efficiency from the epitaxial material, e.g., Ge, one approach is to form a boron (B) doped layer in the epitaxial material to gather more photo-induced electrons. In some embodiments, the concentration of the dopant (e.g., the boron) in the boron doped layer is no greater than other portions of the absorption region 112. For instance, referring to FIG. 1, a lightly doped layer 113 can be formed in proximity to the heterojunction interface 118, such as in proximity to a bottom side of the absorption region 112. That is, the lightly doped layer 113 is formed under the bulk region 112a of the absorption region 112. In some embodiments, the lightly doped layer 113 is a boron-doped layer that the doping concentration is no greater than about 5e16 atoms/cm³. In some embodiments, the thickness of the lightly doped layer 113 is ranging from about 1 Å to about 300 nm. Accordingly, compared with the bulk region 112a of the absorption region 112 (i.e., the region within the absorption region 112 other than the lightly doped layer 113), which has a Ge p-type doped to the doping concentration in a range of from about 5e16 atoms/cm³ to about 5e17 atoms/cm³, the doping concentration in the lightly doped layer 113 is relatively light. In some embodiments, the doping concentration of p-type dopant (e.g., the boron) along a vertical direction from a top side of the absorption region 112 to a bottom side of the absorption region 112 (e.g. see D1 in FIG. 1) may substantially include a decreasing trend.

A lateral connection region 114 extends laterally from the second doped region 108 past outer sidewalls of the absorption region 112 where the lateral connection region 114 includes the same doping type as the second doped region 108. A vertical connection region 116 extends from the lateral connection region 114 and vertically past a bottom surface of the absorption region 112. The vertical connection region 116 includes the same doping type as the lateral connection region 114. Furthermore, the lateral connection region 114 and the vertical connection region 116 form a connection region 124. In some contexts, the connection region 124 is referred to as a “guard ring” as the vertical connection region 116 laterally surrounds the absorption region 112.

A channel region 104 is disposed between the multiplication region 115 and the absorption region 112. The channel region 104 and the multiplication region 115 meet at a second p-n junction 110b. Furthermore, the channel region 104 and the absorption region 112 meet at a third p-n junction 110c. In some embodiments, the channel region 104 is referred to as a third doped region and can include the same doping type as the second doped region 108. In some embodiments, the channel region 104 includes an n-type region with an n-type dopant and the p-type dopant of the multiplication region is disposed between the channel region 104 and the n-type region of the multiplication region. In some embodiments, the channel region 104 has a doping concentration of 1e16 atoms/cm³ to 1e18 atoms/cm³. In some embodiments, the channel region 104 and the bulk region 112a of the absorption region 112 may have substantially the same doping concentration. The channel region 104 is disposed within the semiconductor substrate 102 and thus the multiplication region 115 and the channel region 104 include the semiconductor material. As such, the heterojunction interface 118 extends between the absorption region 112 and the channel region 104. In some embodiments, a lateral width of the channel region 104 is between 0.4 micrometers (μm) to substantially a same lateral width as the absorption region 112, and the channel region 104 can have a height from 0.1 μm to 3 μm.

In some embodiments, during operation of the photodetector device 100, a bias circuit (not shown) biases the first p-n junction 110a above a breakdown voltage. Under this bias condition, when an incident photon 122 (or energy, e.g., from a radiation source) is absorbed in the absorption region 112, an electron-hole pair is created and the electron drifts through the channel region 104 and into a multiplication region 115, which includes the first p-n junction 110a. The electron passes through the second p-n junction 110b between the channel region 104 and the multiplication region 115, and the electron passes through the third p-n junction 110c between the channel region 104 and the absorption region 112. As such, the channel region defines the electron path there by “funneling” or facilitating transfer of the electron through the heterojunction interface 118 at the third p-n junction 110c and into the multiplication region 115. The electron is then accelerated in the multiplication region 115, gaining sufficient kinetic energy to undergo impact ionization, creating a secondary electron-hole pair. The second electron and hole of the second electron-hole pair are in turn accelerated and impact ionized, creating further electron-hole pairs in the multiplication region 115. Further impact ionization of holes and electrons multiply thus rapidly creating a large current (e.g., avalanche current) which can be self-sustaining if the device is biased above a breakdown voltage (e.g., avalanche breakdown). In these conditions, an observable electronic signal is produced, which can be timed in relation to the initial incident photon. After detection, the bias circuit momentarily biases the photodetector device 100 below the breakdown voltage to quench the multiplication, after which the photodetector device 100 can return to its quiescent state ready to detect further incident photons.

Due to the presence of the channel region 104 that is doped at the heterojunction interface 118, the dark current rate can be reduced in some regards compared to other approaches. In photodetector device 100, forming the channel region 104 from a doped material that is opposite of a doping of the absorption region 112, rather than, for example, forming the channel region from intrinsic material, offers several advantages. For example, the third p-n junction 110c increases the electron transfer rate through the heterojunction by “funneling” electrons through the heterojunction interface 118 and to the multiplication region 115 of the semiconductor substrate 102. As a result, the heterojunction interface is enhanced thereby increasing the electron transfer rate at the interface. Meanwhile, current leakage and dark currents that arise as a result of a crystalline mismatch and defects at the heterojunction interface 118 can still be suppressed by a doped Si region surrounded the absorption region 112.

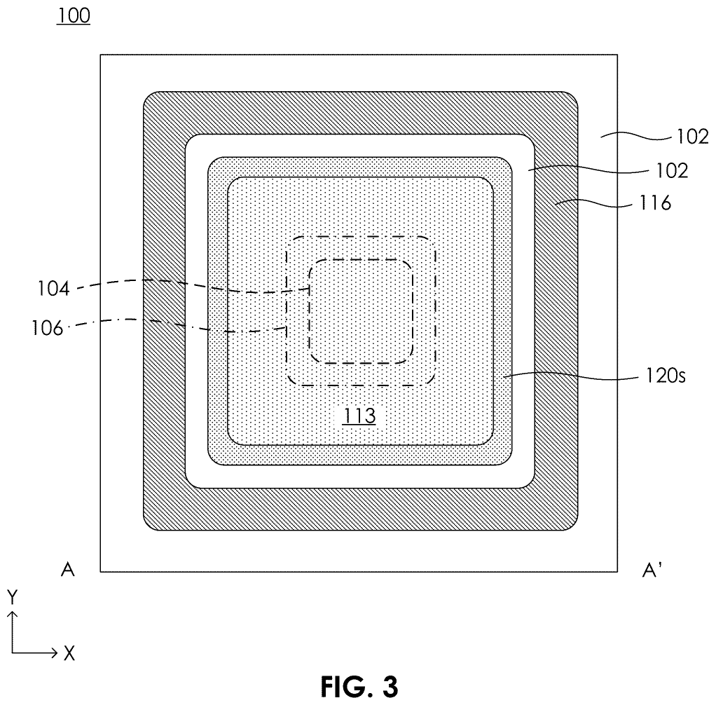

FIG. 2 illustrates a cross-sectional view of some embodiments of a photodetector device 100. FIG. 3 illustrates some embodiments corresponding to a top view of the photodetector device 100 of FIG. 2 at the A-A′ line.

Referring now to FIGS. 2 and 3 concurrently, the photodetector device 100 of FIGS. 2 and 3 may include an epitaxial material (e.g., within the absorption region 112) disposed within the semiconductor substrate 102. A first doped region 106 is arranged in the semiconductor substrate 102 below the epitaxial material. A second doped region 108 is arranged in the semiconductor substrate 102 below the first doped region 106 and abutting the first doped region 106 at a first p-n junction 110a. A third doped region (e.g., the channel region 104) is disposed between the epitaxial material and the first doped region 106. The third doped region abuts the first doped region 106 at a second p-n junction 110b, and the third doped region abuts the epitaxial material at a third p-n junction 110c. As such, the first doped region 106 is disposed on top of the second doped region 108, the third doped region is disposed on top of the first doped region, and the epitaxial material is on top of the third doped region.

A surface region 120 extends around a bottom surface (i.e., a bottom side) and sidewalls (i.e., a lateral side) of the absorption region 112 to the first surface 102A of the semiconductor substrate 102. The surface region 120 includes a doped portion of the semiconductor substrate 102. In some embodiment, the surface region 120 is substantially referred to an interface of Ge and Si that passivated by p-type dopant. In some embodiments, the thickness of the surface region 120 is ranging from about 1 Å to about 200 nm. In some embodiments, the thickness of the lightly doped layer 113 can be greater than the thickness of the surface region 120. In some embodiments, the surface region 120 can have a doping concentration greater than about 5e17 atoms/cm³, which is a region that having relatively heavy p-type implant in Ge for depressing dark current. In some embodiments, the surface region 120 includes a base portion 120b having a central opening corresponding to the channel region 104, and includes a sidewall portion 120s extending upwards along outer sidewalls of the absorption region 112. In some embodiments, the base portion 120b and the sidewall portion 120s have different thicknesses, for example, where the base portion 120b is thinner than the sidewall portion 120s. The multiplication region 115 is disposed within the semiconductor substrate 102 separated from the absorption region 112. The multiplication region 115 includes a first doped region 106 arranged below the absorption region 112, and a second doped region 108 arranged below and abutting the first doped region 106 at the first p-n junction 110a. As such, the channel region 104 extends from the multiplication region 115 and through the surface region 120 to abut the absorption region 112 at the heterojunction interface 118.

In some embodiments, a thickness of the channel region 104 is greater than a thickness of the base portion 120b of the surface region 120. In some embodiments, a width of the channel region 104 is less than a width of the first doped region 106. As such, the base portion 120b of the surface region 120 is separated from the first doped region 106 of the multiplication region 115 by the semiconductor substrate 102. Furthermore, the channel region 104 abuts the multiplication region 115, semiconductor substrate 102, and the surface region 120. The surface region 120 establishes a partial U-shaped cross-sectional (see FIG. 2) profile that extends from the channel region 104 and generally encloses the absorption region 112. From a top-view (see FIG. 3), the surface region 120 is ring-shaped where the surface region 120 laterally surrounds the lightly boron doped layer 113 in the absorption region 112.

Based on the foregoing disclosure, the surface region 120 including the semiconductor material and can be doped with the same doping type as the absorption region 112. In some embodiments, for example, the absorption region 112 is p-type and the surface region 120 is p-type, whereas the doping concentration thereof are different. In some examples, the absorption region 112 is Ge doped p-type and the surface region 120 is Si doped p-type. Because the absorption region 112 and the surface region 120 include different bandgap materials, the absorption region 112 and the surface region 120 abut at the heterojunction interface 118. The surface region 120 around the absorption region 112 may reduce current leakage, and thus may mitigate dark current that arises due to stress, dislocations, and the like arising at the Ge—Si interface region. In addition, as aforementioned, by using the lightly boron doped layer 113 in the absorption region 112, such layer in proximity to the channel region 104, may increase the photo-electron collection efficiency from the bulk region 112a in the absorption region 112 through gathering more photo-induced electrons.

To be more detailed, in some embodiments, the structure surrounded by the semiconductor substrate 102, which includes the surface region 120 and the absorption region 112 surrounded by the surface region 120, may have variations in the doping concentration among different portions thereof. In some embodiments, the bulk region 112a in the absorption region 112 can have a first p-type doping concentration that is in a range from about 5e16 atoms/cm³ to about 5e17 atoms/cm³; the lightly doped layer 113 in the absorption region 112 can have a second p-type doping concentration that is no greater than about 5e16 atoms/cm³; and the surface region 120 can have a third p-type doping concentration that is greater than about 5e17 atoms/cm³.

Therefore, in some embodiments, a regional p-type doping concentration along a vertical direction from a top side of the absorption region 112 to a bottom side of the absorption region 112 (i.e., along the bulk region 112a towards the lightly boron doped layer 113, see D1 in FIG. 1) substantially includes a decreasing trend.

On the other hand, in some embodiments, a trend of a cross-regional p-type doping concentration along a vertical direction from a top side of the absorption region 112 to a bottom side of the surface region 120 substantially includes a turning point within the lightly doped layer 113, for instance, in proximity to an interface between the lightly doped layer 113 and the surface region 120, because the p-type doping concentration of the lightly doped layer 113 (i.e., the second p-type doping concentration) is less than each of the p-type doping concentration of the bulk region 112a (i.e., the first p-type doping concentration) and the surface region 120 (i.e., the third p-type doping concentration). In some embodiments, it can be said that a cross-regional p-type doping concentration along a vertical direction from a top side of the absorption region 112 to a bottom side of the surface region 120 (e.g., see D2 in FIG. 2) substantially includes a decreasing trend (i.e., from the bulk region 112a towards the lightly doped layer 113) and an increasing trend (i.e., from the lightly doped layer 113 towards the surface region 120) sequentially.

In some embodiments, a contact structure 126 extends from the vertical connection region 116 to a top surface of the semiconductor substrate 102. The contact structure 126 can, for example, include the same semiconductor material and same doping type as the vertical connection region 116. In some embodiments, the contact structure 126 has a higher doping concentration than the vertical connection region 116. Thus, the connection region 124 can include the contact structure 126, the lateral connection region 114 and the vertical connection region 116, which are separated from the absorption region 112 and the surface region 120 by the semiconductor substrate 102.

The lateral connection region 114 extends laterally from the second doped region 108 past outer sidewalls of the first doped region 106 and outer sidewalls of the absorption region 112. The vertical connection region 116 extends vertically from the lateral connection region 114 past the channel region 104 and a bottom surface of the absorption region 112. In some contexts, the connection region 124 may be referred to as a “ring-shaped” because the vertical connection region 116 laterally surrounds the absorption region 112 when viewed from above (see FIG. 3). In some embodiments, the second doped region 108, and the connection region 124 collectively establish a U-shaped cross-sectional profile that generally enclose the first doped region 106, the channel region 104, and the absorption region 112 when viewed in a cross-sectional view (see FIG. 2). In some embodiments, an isolation layer 138 is disposed within the semiconductor substrate 102 below the connection region 124. The isolation layer 138 can, for example, include the semiconductor material of the semiconductor substrate 102 and can be doped (e.g., p-type).

In some embodiments, a dielectric structure 132 extends over the first surface 102A of the semiconductor substrate 102. The dielectric structure 132 can be or include a silicon dioxide or a low-k dielectric material. In some embodiments, an epitaxial cap 128 is disposed within the dielectric structure 132, where the epitaxial cap 128 extends from an upper surface of the absorption region 112. The epitaxial cap 128 extends past outer sidewalls of the absorption region 112 and over a top surface of the sidewall portion 120s of the surface region 120. In some embodiments, a plurality of conductive contacts 134, such as metal contacts, extend through the dielectric structure 132. The conductive contacts 134 can couple to the contact structure 126 and one of the conductive contacts 134 extend through the epitaxial cap 128 to couple to the absorption region 112. In some embodiments, the epitaxial cap 128 can be boron-doped, wherein the doping concentration of the epitaxial cap 128 can be substantially identical to that of the surface region 120. In some embodiments, a plurality of metal lines 136 are coupled to the conductive contacts 134 and operably coupled to a bias circuit (not shown), which may include semiconductor devices formed on the semiconductor substrate 102 or formed on another semiconductor substrate. For example, if the semiconductor devices are formed on the semiconductor substrate 102, the semiconductor devices may include transistors including fins and/or a gate electrode disposed on the first surface 102A of the semiconductor substrate 102, or alternatively may include transistors including fins and/or a gate electrode disposed on the second surface 102B of the semiconductor substrate 102 in which case a through via may extend through the semiconductor substrate 102 to facilitate the operable coupling.

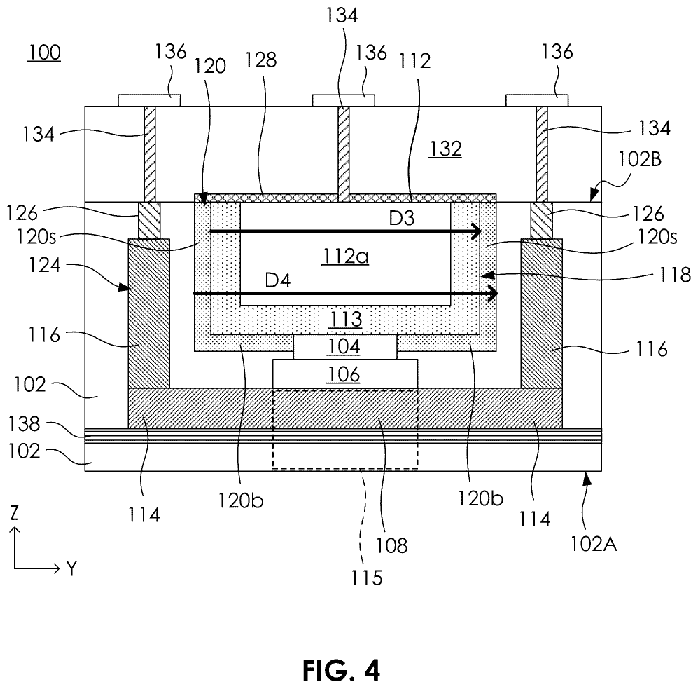

In some embodiments, the lightly doped layer 113 (e.g., a lightly boron doped layer) in the absorption region 112 can be formed by the operation of implanting, and therefore the lightly boron doped layer 113 may be located under the bulk region 112a and in proximity to a bottom side of the absorption region 112, as illustrated in FIGS. 1 and 2. In other embodiments, the lightly boron doped layer 113 in the absorption region 112 can be formed during the growth of the epitaxial material (e.g., Ge) in a cavity of the semiconductor substrate 102. Referring to FIG. 4, since the epitaxial material with boron dopant is grown from the inner surfaces of the cavity of the semiconductor substrate 102, the lightly doped layer 113 formed thereby can have a U-shaped cross-sectional profile along a bottom side and a lateral side of the bulk region 112a. In such embodiments, the lightly doped layer 113 also in proximity to the heterojunction interface 118 (i.e., the Ge—Si interface). Generally, the formation of the lightly doped layer 113 under the manner of epitaxial growth, the concentration of dopant, and the thickness of the lightly doped layer 113 can be well-controlled, with less process variation compared to an implanting process.

Therefore, in some embodiments, a trend of a regional p-type doping concentration along a horizontal direction between two sides (from a cross sectional view) of the absorption region 112 (e.g., see D3 in FIG. 4) can substantially include a decreasing trend and an increasing trend, each can be obtained in proximity to the two sides of the bulk region 112a, because the bulk region 112a is laterally surrounded by the lightly doped layer 113 and the doping concentration of the lightly doped layer 113 is less than that of the bulk region 112a.

Moreover, considering that the surface region 120 can extend around the bottom side and the two lateral sides (from a cross sectional view) of the absorption region 112, in some embodiments, a trend of a cross-regional p-type doping concentration along a horizontal direction between two sides (from a cross sectional view) of the surface region 120 (e.g., see D4 in FIG. 4) can substantially include two turning points, since the p-type doping concentration of the lightly doped layer 113 (i.e., the second p-type doping concentration) is less than the p-type doping concentration of the regions sandwiching the lightly doped layer 113.

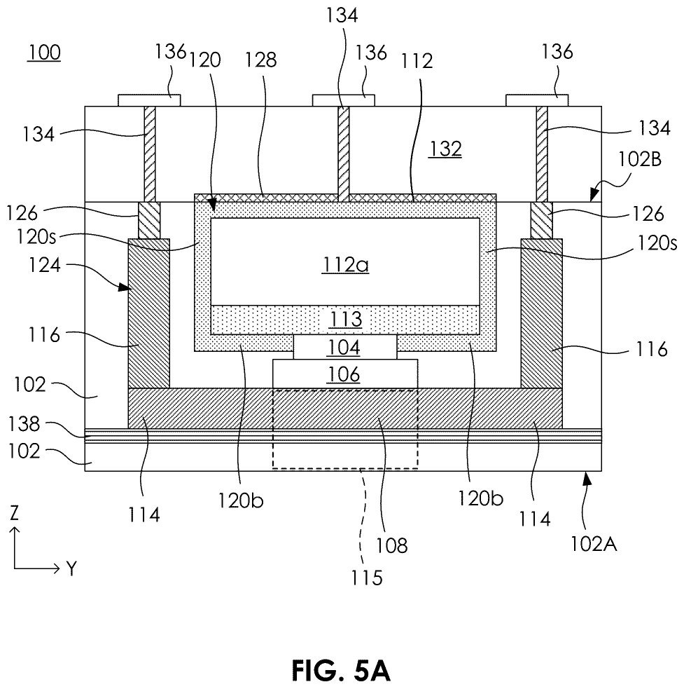

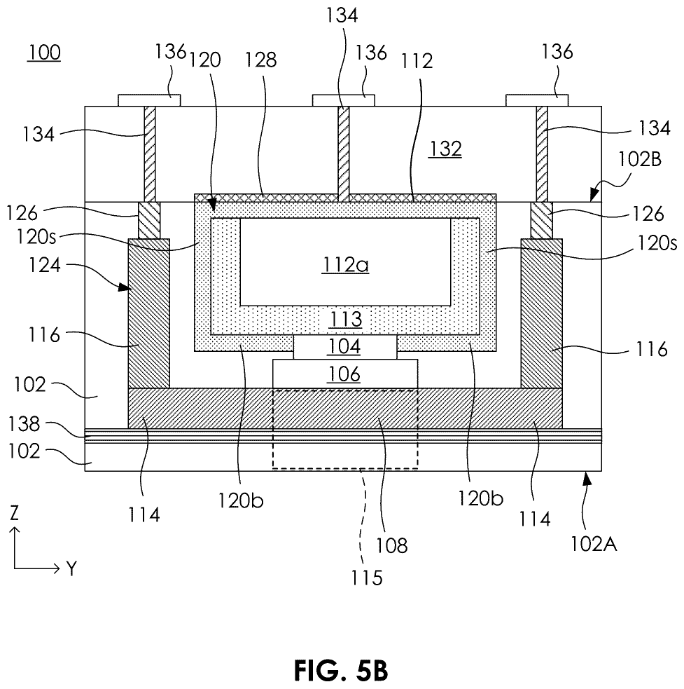

As shown in FIGS. 5A and 5B, in some embodiments, the surface region 120 can further extending to cover a top side of the absorption region 112, while the lightly boron doped layer 113 can be formed either by the operation of implanting or by the process of epitaxial growth.

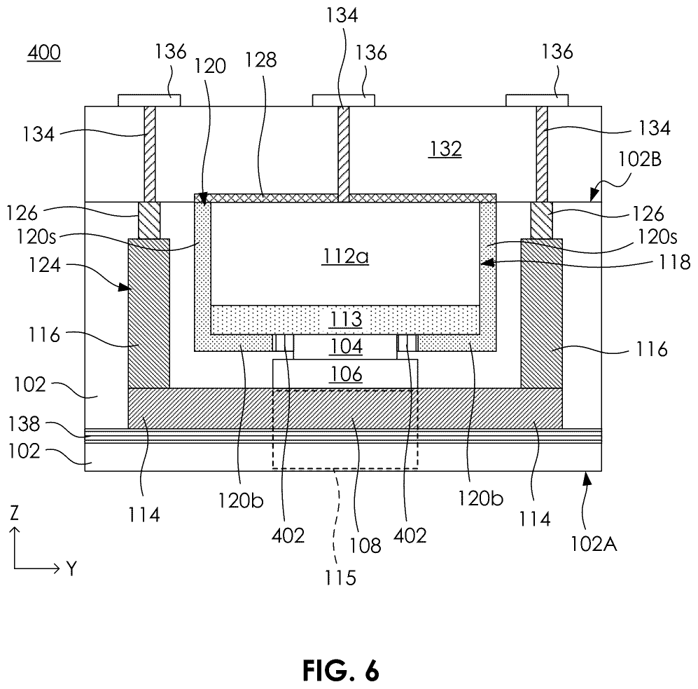

FIG. 6 illustrates some embodiments of a cross-sectional view of a photodetector device 400 with a base portion 120b of a surface region 120 that is counter doped. That is, the surface region 120 is doped with a first type of dopant, then subsequently doped with a second type of dopant that is different than the first type.

Photodetector device 100 of FIG. 6 shows similar features as FIG. 2 with an alternative embodiment for the base portion 120b of the surface region 120. The base portion 120b includes the same doping type as the sidewall portion 120s of the surface region 120. A subset base portion 402 of the base portion 120b has a different doping concentration relative to the sidewall portion 120s. The subset base portion 402 is disposed along outer sidewalls of the channel region 104 and abutting the absorption region 112. The subset base portion 402 is formed according to a counter doping process. The subset base portion 402 is formed with a first doping type according to a first doping process and subsequently a second doping type according to a second doping process where the first and second doping types are different. For example, in some embodiments, the subset base portion 402 is formed with an n-type dopant (e.g., the first doping type) during the first doping process, then a mask is placed over the channel region 104 and the subset base portion 402 in conjunction with the base portion 120b is further formed with a p-type dopant (e.g., the second doping type) during the second doping process. The second doping process counteracts the effects of the first doping process and forms the subset base portion 402 to be the second doping type according to the counter doping process. This process has the advantage of minimizing the processing steps to form the channel region 104 and the surface region 120.

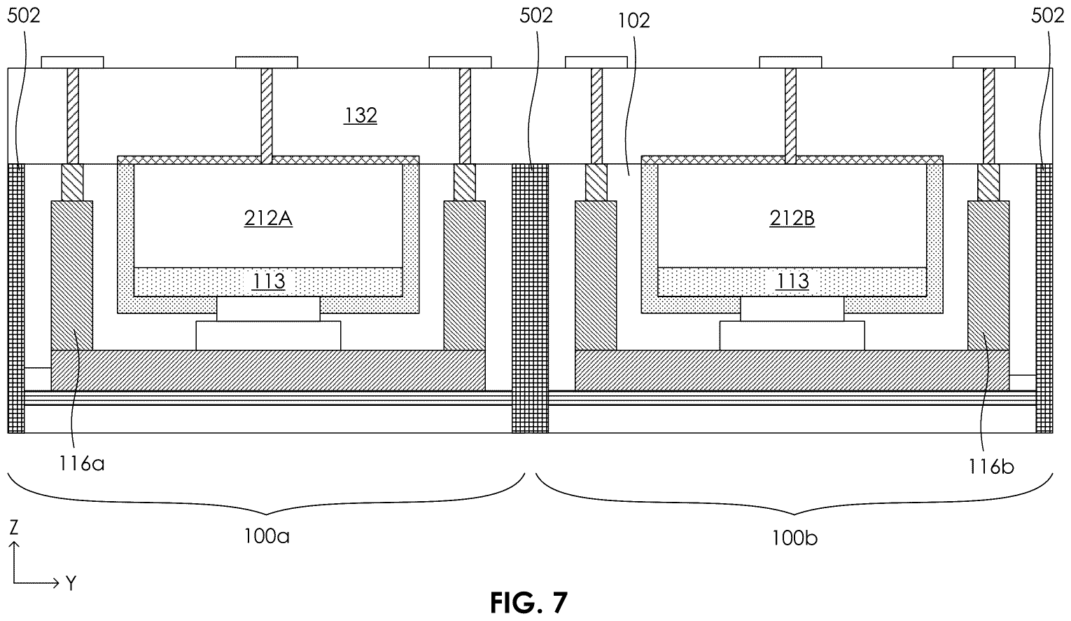

FIG. 7 shows some embodiments of a cross-sectional view of some embodiments where first and second photodetector devices are arranged side-by-side in a semiconductor substrate 102 and separated by an isolation structure 502. In FIG. 7, a first photodetector device 100a and a second photodetector device 100b have features as previously described in FIG. 2 or 4 (here uses FIG. 2 as an example). Thus, in FIG. 7, a first vertical connection region 116a laterally surrounds a first absorption region 212A of the first photodetector device 100a, and a second vertical connection region 116b laterally surrounds a second absorption region 212B of the second photodetector device 100b. The isolation structure 502 separates the first vertical connection region 116a from the second vertical connection region 116b and defines an isolation structure 502. In some embodiments, the isolation structure 502 is intrinsic (e.g., monocrystalline silicon). In other embodiments, the isolation structure 502 is a deep trench isolation structure made of a dielectric material and/or including a doped portion of the semiconductor substrate 102 (e.g., doped p-type). It will be appreciated that any number of photodetector devices can be arranged in the semiconductor substrate 102, and they can be arranged in an array, for example, that includes a number of rows and columns. Also, although FIG. 7 is illustrated in an example where the first photodetector device 100a and the second photodetector device 100b correspond to the photodetector device of FIG. 2, in other embodiments the first photodetector device 100a and the second photodetector device 100b could correspond to other illustrated embodiments described herein, or combination thereof.

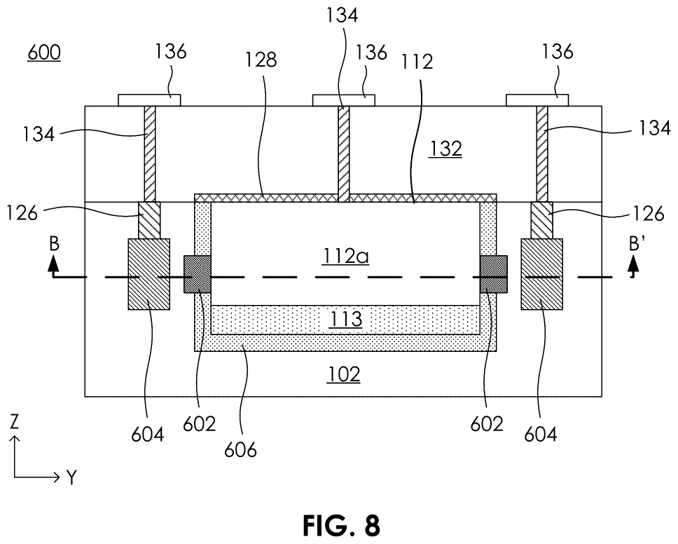

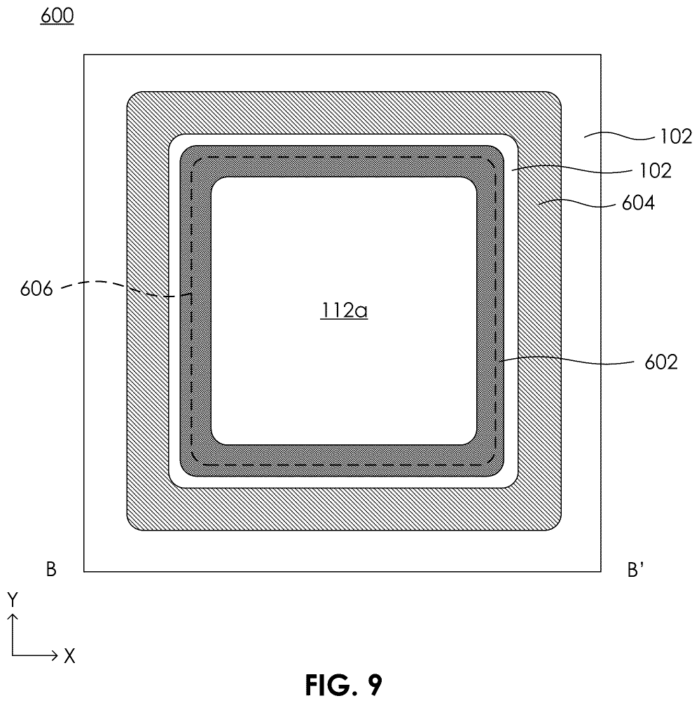

FIG. 8 illustrates a cross-sectional view of some alternative embodiments of a photodetector device 600 with a channel region 602 at a heterojunction interface 118. FIG. 9 illustrates some embodiments corresponding to a top view of the photodetector device 600 at the B-B′ line of FIG. 8. In some embodiments, the photodetector device 600 is a PN or a PIN photodetector.

Referring now to FIGS. 8 and 9 concurrently, photodetector device 600 shows alternative features relative to photodetector device 100 with a channel region 602 that is ring shaped. The absorption region 112 is disposed within the semiconductor substrate 102. A surface region 606 is disposed along an outer perimeter of the absorption region 112 in a cross-sectional view (see FIG. 8). In some embodiments, the surface region 606 and the absorption region 112 of FIGS. 8 and 9 are analogous to the surface region 120 and absorption region 112 of FIGS. 2-7. A first doped region 604 is laterally separated from the surface region 606 by the semiconductor substrate 102. The first doped region 604 is coupled to conductive contacts 134 through the contact structure 126.

A channel region 602 meets the absorption region 112 at the heterojunction interface 118 at opposing sidewalls of the absorption region 112. The channel region 602 extends from the semiconductor substrate 102 and through the surface region 606. Furthermore, the channel region 602 is separated from the first doped region 604 by the semiconductor substrate 102. That is, intrinsic substrate of the semiconductor substrate 102 is disposed between the channel region 602 and the first doped region 604. The channel region 602 defines a ring shape from a top view (see FIG. 9) that laterally surrounds the absorption region 112.

In some embodiments, the first doped region 604 and the channel region 602 include the same doping type, for example, the first doping type. The absorption region 112 includes a second doping type that is different than the first doping type. For example, the first doping type can be n-type and the second doping type can be p-type. Thus, the channel region 602 meets the absorption region 112 at a p-n junction which is co-located with the heterojunction interface 118 at a sidewall of the channel region 602. As such, when photodetector device 600 is biased and excited by a radiation source, a current is generated from the absorption region 112, through the channel region 602, through the semiconductor substrate 102 and to the first doped region 604. The channel region 602 facilitates electron transfer through the heterojunction interface 118.

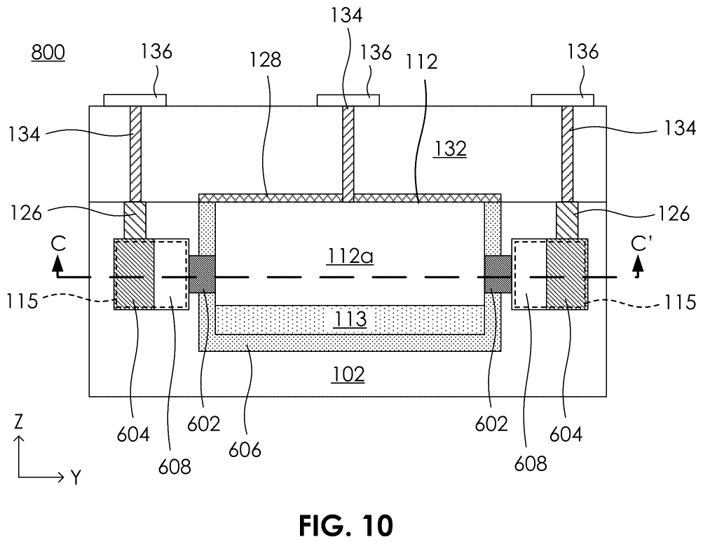

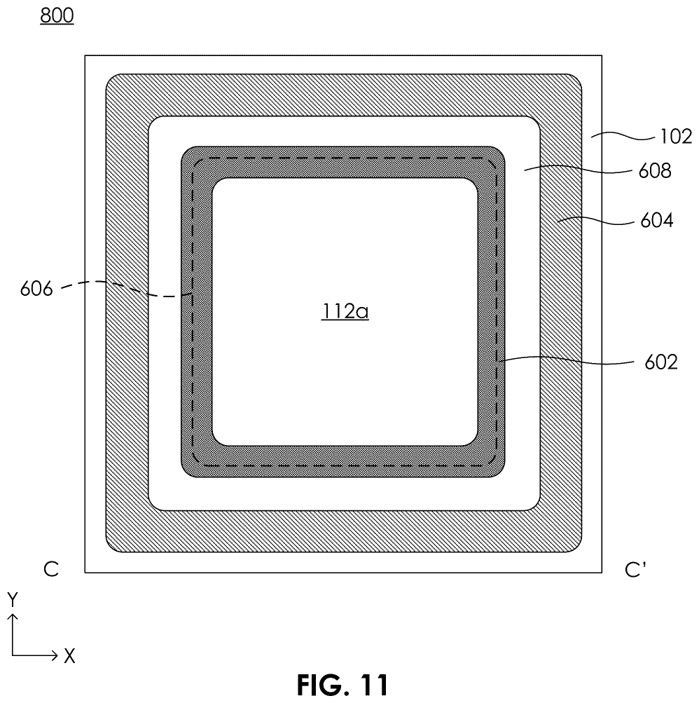

FIG. 10 illustrates a cross-sectional view of some alternative embodiments of a photodetector device 800 with a channel region at a heterojunction interface. FIG. 11 illustrates some embodiments corresponding to a top view of the photodetector device 800 at a C-C′ line of FIG. 10. In some embodiments, the photodetector device 800 is an avalanche photodetector or a single-photon avalanche diode.

Referring now to FIGS. 10 and 11 concurrently, photodetector device 800 shows alternative features relative to photodetector device 600 where a second doped region 608 is disposed between the channel region 602 and the first doped region 604. In some embodiments the channel region 602 is referred to as a third doped region. The first doped region 604 and the channel region 602 include the same doping type as discussed in accordance with FIGS. 8 and 9. The second doped region 608 includes a second doping type that is different than the first doping type of the channel region 602 and the first doped region 604. For example, in some embodiments the first doping type is n-type and the second doping type is p-type. As such, a first p-n junction is formed between the first doped region 604 and the second doped region 608, a second p-n junction is formed between the second doped region 608 and the channel region 602, and a third p-n junction is formed between the channel region 602 and the absorption region 112 at the heterojunction interface 118. The first doped region 604 and the second doped region 608 form a multiplication region 115 of the photodetector device 600. The multiplication region 115 laterally surrounds the channel region 602 and the absorption region 112 thus forming a ring shaped multiplication region from a top view (see FIG. 11). The channel region 602 facilitates electron transfer through the heterojunction interface 118 and into the multiplication region 115 as described in accordance with FIGS. 1 and 2.

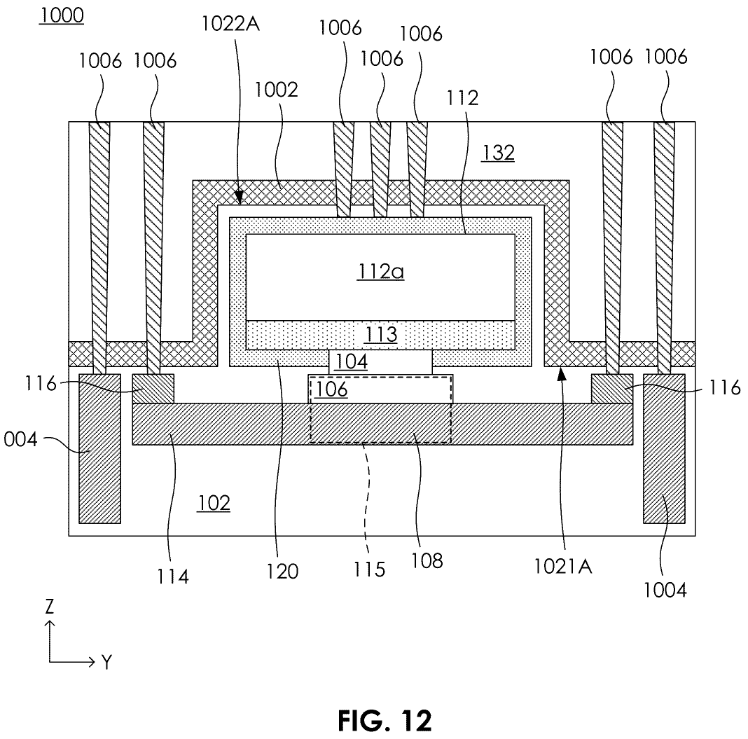

FIG. 12 illustrates some embodiments corresponding to a cross-sectional view of a mesa type photodetector device 1000 with a channel region at a heterojunction interface. Mesa type photodetector device 1000 shows an alternative embodiment where some aspects of the photodetector device are disposed between two upper surfaces of the semiconductor substrate 102. For example, one or more of the absorption region 112, the surface region 120, or the channel region 104 can extend above a first portion 1021A of the first surface of the semiconductor substrate 102. In some embodiments, a second portion 1022A of the first surface of the semiconductor substrate 102 extends over the absorption region 112 and the surface region 120. In some embodiments, the multiplication region 115 is disposed below the first portion 1021A. An isolation structure 1004 is disposed within the semiconductor substrate 102 connected to metal contacts 1006 and laterally offset from the vertical connection region 116. The isolation structure 1004 isolates the photodetector from surrounding devices within the semiconductor substrate 102. A liner 1002 is disposed over the semiconductor substrate 102 extending along the first portion 1021A of the first surface and the second portion 1022A of the first surface of the semiconductor substrate 102. In some embodiments, the liner 1002 can be, for example, a dielectric liner. The metal contacts 1006 contact the surface region and the vertical connection region 116 to bias the mesa type photodetector device 1000.

In one exemplary aspect, a photodetector device is provided. The photodetector device includes a substrate; an absorption region disposed within the substrate and in proximity to a surface of the substrate; a multiplication region disposed within the substrate and separated from the absorption region; and a channel region disposed between the multiplication region and the absorption region. The channel region and the multiplication region meet at a p-n junction. The absorption region includes a bulk region having a first p-type doping concentration; and a lightly doped layer under the bulk region and in proximity to a bottom side of the absorption region. The lightly doped layer has a second p-type doping concentration less than the first p-type doping concentration.

In another exemplary aspect, a photodetector device is provided. The photodetector device includes a substrate; an absorption region disposed within the substrate and in proximity to a surface of the substrate, a multiplication region disposed within the substrate and under the absorption region; and a channel region disposed between the multiplication region and the absorption region. The channel region and the multiplication region meet at a p-n junction. The absorption region includes a bulk region having a first p-type doping concentration; and a lightly doped layer laterally surrounding the bulk region. The lightly doped layer has a second p-type doping concentration less than the first p-type doping concentration.

In yet another exemplary aspect, a photodetector device is provided. The photodetector device includes a silicon substrate; an germanium-based absorption region disposed within the silicon substrate and in proximity to a surface of the silicon substrate; a lightly doped layer in proximity to an interface between the silicon substrate and the germanium-based absorption region, the lightly doped layer having a doping concentration no greater than about 5e16 atoms/cm³; a multiplication region disposed within the silicon substrate and under the germanium-based absorption region; and a channel region disposed between the multiplication region and the germanium-based absorption region. The channel region and the multiplication region meet at a p-n junction.

The foregoing outlines structures of several embodiments so that those skilled in the art may better understand the aspects of the present disclosure. Those skilled in the art should appreciate that they may readily use the present disclosure as a basis for designing or modifying other operations and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A photodetector device, comprising:
a substrate;
an absorption region disposed within the substrate and in proximity to a surface of the substrate, the absorption region comprising:
a bulk region having a first p-type doping concentration; and
a lightly doped layer under the bulk region and in proximity to a bottom side of the absorption region, wherein the lightly doped layer has a second p-type doping concentration less than the first p-type doping concentration;
a multiplication region disposed within the substrate and separated from the absorption region; and
a channel region disposed between the multiplication region and the absorption region, wherein the channel region and the multiplication region meet at a p-n junction.

2. The photodetector device of claim 1, wherein the second p-type doping concentration is no greater than about 5e16 atoms/cm³.

3. The photodetector device of claim 1, wherein a thickness of the lightly doped layer is ranging from about 1 Å to about 300 nm.

4. The photodetector device of claim 1, wherein a regional p-type doping concentration along a vertical direction from a top side of the absorption region to a bottom side of the absorption region substantially comprises a decreasing trend.

5. The photodetector device of claim 1, wherein the channel region comprises an n-type region, and the multiplication region comprises an n-type region and a p-type region, wherein the p-type region of the multiplication region is disposed between the channel region and the n-type region of the multiplication region.

6. The photodetector device of claim 1, further comprising:
a surface region extending around a bottom side and a lateral side of the absorption region, wherein the surface region has a third p-type doping concentration different from each of the first p-type doping concentration and the second p-type doping concentration.

7. The photodetector device of claim 1, wherein the first p-type doping concentration is in a range of from about 5e16 atoms/cm³ to about 5e17 atoms/cm³.

8. The photodetector device of claim 6, wherein a trend of a cross-regional p-type doping concentration along a vertical direction from a top side of the absorption region to a bottom side of the surface region substantially comprises a turning point in proximity to an interface between the lightly doped layer and the surface region.

9. The photodetector device of claim 6, wherein a cross-regional p-type doping concentration along a vertical direction from a top side of the absorption region to a bottom side of the surface region substantially comprises a decreasing trend and an increasing trend sequentially.

10. A photodetector device, comprising:
a substrate;
an absorption region disposed within the substrate and in proximity to a surface of the substrate, the absorption region comprising:
a bulk region having a first p-type doping concentration; and
a lightly doped layer laterally surrounding the bulk region, wherein the lightly doped layer has a second p-type doping concentration less than the first p-type doping concentration;
a multiplication region disposed within the substrate and under the absorption region; and
a channel region disposed between the multiplication region and the absorption region, wherein the channel region and the multiplication region meet at a p-n junction.

11. The photodetector device of claim 10, wherein the lightly doped layer has a U-shaped cross-sectional profile along a bottom side and a lateral side of the bulk region.

12. The photodetector device of claim 10, wherein the absorption region comprises boron-doped germanium.

13. The photodetector device of claim 10, wherein a trend of a regional p-type doping concentration along a horizontal direction between two sides of the absorption region substantially comprises a decreasing trend and an increasing trend.

14. The photodetector device of claim 10, further comprising:
a surface region extending around a bottom side and a lateral side of the absorption region, wherein the surface region has a third p-type doping concentration different from each of the first p-type doping concentration and the second p-type doping concentration.

15. The photodetector device of claim 14, wherein the third p-type doping concentration is greater than about 5e17 atoms/cm³.

16. The photodetector device of claim 14, wherein the third p-type doping concentration is greater than the first p-type doping concentration.

17. A photodetector device, comprising:
a silicon substrate;
a germanium-based absorption region disposed within the silicon substrate and in proximity to a surface of the silicon substrate;
a lightly doped layer in proximity to an interface between the silicon substrate and the germanium-based absorption region, the lightly doped layer having a doping concentration no greater than about 5e16 atoms/cm³;
a multiplication region disposed within the silicon substrate and under the germanium-based absorption region; and
a channel region disposed between the multiplication region and the germanium-based absorption region, wherein the channel region and the multiplication region meet at a p-n junction.

18. The photodetector device of claim 17, further comprising a surface region extending around a bottom side and a lateral side of the germanium-based absorption region.

19. The photodetector device of claim 18, wherein a trend of a cross-regional p-type doping concentration along a vertical direction from a top side of the germanium-based absorption region to a bottom side of the surface region substantially comprises a turning point in proximity to the bottom side of the germanium-based absorption region.

20. The photodetector device of claim 19, wherein the germanium-based absorption region comprises a bulk region laterally surrounded by the lightly doped layer, a thickness of the lightly doped layer is greater than a thickness of the bulk region.
